(19) United States
(12) Patent Application Publication
(10) Pub. No.: US 2021/0365019 A1
(43) Pub. Date: Nov. 25, 2021

(54) A MONITOR FOR A MULTI-PARAMETER MANUFACTURING PROCESS

(71) Applicant: Commonwealth Scientific and Industrial Research Organisation, Acton (AU)

(72) Inventors: Nick Van Beest, Acton (AU); Guido Governatori, Acton (AU)

(21) Appl. No.: 17/273,638

(22) PCT Filed: Aug. 26, 2019
(86) PCT No.: PCT/AU2019/050897

§ 371 Date: Mar. 4, 2021

(30) Foreign Application Priority Data
Sep. 5, 2018 (AU) 2018903302

(51) Int. Cl. G05B 19/418

(52) U.S. Cl. CPC G05B 19/41885; G05B 2219/32379

(57) ABSTRACT

The present disclosure relates to manufacturing a pharmaceutical compound according to a manufacturing process. The manufacturing process comprises process parameters and rules that use the process parameters as literals. A control system determines a partition of the rules into subsets of rules, each being independent from the other subsets of rules in relation to the literals used in the rules. The controller creates simplified representations of the manufacturing process, which comprise the literals from a corresponding subset of rules and are created by eliminating literals used by other subsets of rules. The controller checks compliance of the manufacturing process based on the simplified representations of the manufacturing process by comparing values of the literals of a current process execution against literals in the simplified representations and adjusts the manufacturing process where the comparing identifies a difference. The controller repeats the steps of checking and adjusting until no differences are identified.

### CROSS-REFERENCE TO RELATED APPLICATIONS

The present application claims priority from Australian Provisional Patent Application No 2018903302 filed on 5 Sep. 2018, the contents of which are incorporated herein by reference in their entirety.

### TECHNICAL FIELD

The present disclosure relates to monitoring processes and in particular, but not limited to, monitoring a current operation of a pharmaceutical manufacturing plant.

### BACKGROUND

Pharma manufacturing is the process of industrial-scale synthesis of pharmaceutical drugs. The process of drug manufacturing can be broken down into a series of unit operations, such as milling, granulation, coating, tablet pressing, and others. Before a drug can be manufactured at any scale, much work goes into the actual formulation of the drug. Formulation development scientists evaluate a compound for uniformity, stability and many other factors. After the evaluation phase, a solution is developed to deliver the drug in its required form such as solid, semi-solid, immediate or controlled release, tablet or capsule. A wide range of excipients may be blended together to create the final blend used to manufacture the solid dosage form. The range of materials that may be blended (excipients, API), presents a number of variables which are addressed to achieve products of acceptable blend uniformity. These variables may include the particle size distribution (including aggregates or lumps of material), particle shape (spheres, rods, cubes, plates, and irregular), presence of moisture (or other volatile compounds), and particle surface properties (roughness, cohesivity). During the drug manufacturing process, milling is often required in order to reduce the average particle size in a drug powder. There are a number of reasons for this, including increasing homogeneity and dosage uniformity, increasing bioavailability, and increasing the solubility of the drug compound. Granulation can be described as the opposite of milling; it is the process by which small particles are bound together to form larger particles, called granules. Granulation is used for several reasons. Granulation prevents the “demixing” of components in the mixture, by creating a granule which contains all of the components in their required proportions, improves flow characteristics of powders (because small particles do not flow well), and improves compaction properties for tablet formation. Hot melt extrusion may be utilized in pharmaceutical solid oral dose processing to enable delivery of drugs with poor solubility and bioavailability. Hot melt extrusion may be used to molecularly disperse poorly soluble drugs in a polymer carrier increasing dissolution rates and bioavailability. The process involves the application of heat, pressure and agitation to mix materials together and ‘extrude’ them through a die. Twin-screw high shear extruders blend materials and simultaneously break up particles. The resulting particles can be blended and compressed into tablets or filled into capsules.

This shows that pharma manufacturing is complex and involves a large number of parameters that need to be within their correct nominal ranges and steps that need to follow each other in a prescribed nominal sequence. At the same time, there is a trend towards lean manufacturing and digital manufacturing. However, these new ways of business organisation require technical solutions as enablers. There is currently a challenge of ensuring that the processes by all entities are compliant with an overarching rule set.

There is therefore a need for a technical process that can check the compliance of a large number of rules. However, with increasingly complex processes, the number of checks that need to be performed grow quickly. For example, the legislation on fair work in Australia has over 1,000 terms and realistic processes to be checked for compliance comprise 30 to 60 activities. This results in a complexity in the order of 2\hat{ }60*2\hat{ }1000=2\hat{ }1060. Such numbers are impractical or effectively impossible for current standard computer architecture to deal with as it would take years to check a process for compliance. So there is a need for a method of compliance checking of a process that addresses the problem of complexity such that it can be performed by existing, limited computer hardware.

Another problem with complex manufacturing and other technical processes is that users who are tasked with monitoring the correct operation of the process are often overwhelmed by the large number of parameters, rules and conditions. Especially, if an error occurs at one point in the process, typically a large number of errors are caused as a result of the first error. It is then virtually impossible for the user to discern where the first error occurred or which part of the process needs to be attended to. This may be particularly important with safety relevant processes, such as aeroplanes, space vehicles or nuclear power plants, where decisions need to be made quickly to avert a major disaster.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

There is provided a method for manufacturing a pharmaceutical compound according to a manufacturing process. The manufacturing process comprises multiple process parameters and multiple rules that use the multiple process parameters as literals. The method comprises:

determining a partition of the rules into multiple subsets of rules, each subset of rules being independent from the other subsets of rules in relation to the literals used in the respective rules;

creating multiple simplified representations of the manufacturing process, wherein each of the multiple simplified representations comprises the one or more literals from a corresponding one of the multiple subsets of rules and is created by eliminating literals used by other subsets of rules;

checking compliance of the manufacturing process based on the multiple simplified representations of the manufacturing process by comparing values of the literals of a current process execution against literals in the multiple simplified representations;

adjusting the manufacturing process where the comparing identifies a difference; and

repeating the steps of checking and adjusting until no differences are identified.

The process may comprise multiple process parameters and multiple rules that use the multiple process parameters as literals. The method may comprise:

determining a partition of the rules into multiple subsets of rules, each subset of rules being independent from the other subsets of rules in relation to the literals used in the respective rules;

creating multiple simplified representations of the process, wherein each of the multiple simplified representations comprises the one or more literals from a corresponding one of the multiple subsets of rules and is created by eliminating literals used by other subsets of rules;

checking compliance of the manufacturing process based on the multiple simplified representations of the manufacturing process by comparing values of the literals of a current process execution against literals in the multiple simplified representations.

Creating each of the multiple simplified representations may comprise creating a directed graph with nodes consisting of places and transitions. The directed graph may be a petri net.

Creating the multiple simplified representations may comprise labelling nodes in the graph as silent where the literal corresponding to that node is not included in the corresponding one of the multiple subsets of rules. Creating the multiple simplified representations may comprise simplifying the graph by removing silent nodes. Creating the multiple simplified representations may comprise creating a graph including states such that the process is in one of the states of the representation. The graph may be a prime event structure and the method comprises simplifying the prime event structure by removing silent nodes associated with the literals from the other subset of rules. Removing the silent nodes may be performed in a behaviour-preserving manner.

The method may further comprise converting the simplified representation of the manufacturing process to a Kripke structure and checking compliance based on the Kripke structure. The method may further comprise linearising independent concurrent branches of the Kripke structure.

The multiple simplified representations may comprise states associated with values for literals and checking each of the multiple simplified representations may comprise traversing the states according to the current process execution and at each state comparing values of the literals of the current process execution against the literals of the current state in the simplified presentation.

The method may further comprise, upon determining non-compliance by detecting a difference between the values of the literals of the current process execution and the literals of one of the multiple simplified structures, generating a graphical user interface indicative of the one of the multiple simplified structures for which the difference was detected. The graphical user interface may be indicative of the subset of rules that is associated with the one of the multiple simplified structures for which the difference was detected. The user interface may be indicative of the one or more literals from that subset of rules.

Computer software that, when executed by a computer system, causes the computer system to perform the method described above.

A computer system for monitoring a process, the computer system comprising:

a computer memory to store multiple process parameters and multiple rules that use the multiple process parameters as literals;

a processor configured to:
determine a partition of the rules into multiple subsets of rules, each subset of rules being independent from the other subsets of rules in relation to the literals used in the respective rules;
create multiple simplified representations of the process, wherein each of the multiple simplified representations comprises the one or more literals from a corresponding one of the multiple subsets of rules and is created by eliminating literals used by other subsets of rules;
check compliance of the manufacturing process based on the multiple simplified representations of the manufacturing process by comparing values of the literals of a current process execution against literals in the multiple simplified representations; and

an output port to provide an indication of the check of compliance to a user.

Optional features described of any aspect of method, computer readable medium or computer system, where appropriate, similarly apply to the other aspects also described here.

### BRIEF DESCRIPTION OF DRAWINGS

An example will now be described with reference to the following drawings:

FIG. 1 illustrates a method for monitoring a manufacturing process.

FIG. 2 illustrates an example for a process in the form of a Business Process Model and Notation (BPMN). It is noted that despite the name “Business” process, the BPMN can equally be used for the representation of technical processes, such as manufacture or control of machinery, such as aeroplanes.

FIG. 3 illustrates the result of the subsequent transformation from the BPMN model of FIG. 2 into a Petri net.

FIG. 4 shows a rule-specific Petri net as a result of applying R₁ to the Petri net in FIG. 3.

FIG. 5a shows an example prime event structure (PES).

FIG. 5b shows PES prefix unfolding without reduction.

FIGS. 6a and 6b illustrate PES prefix unfolding specific to R₁.

FIG. 7 illustrates a verifiable model created from the rule-specific Petri net in FIG. 6b.

FIG. 8 shows an original Kripke structure.

FIG. 9 shows a linearized Kripke structure based the same rules and the Kripke structure in FIG. 8.

FIG. 10 illustrates a computer system for monitoring a process.

FIG. 11 illustrates a data flow representation of a computer implementation of the method in FIG. 1.

### DESCRIPTION OF EMBODIMENTS

The following disclosure relates to a method and a system for executing or monitoring a current operation of a process that addresses the above problem of complexity. Using the methods disclosed herein, processes can be monitored that would otherwise be too complex for existing computer systems. In one example, this disclosure applies to a pharma manufacturing process with the above parameters and sequences in addition to further process steps and further parameters. In those examples, the term “nominal operation” refers to process variables/parameters and sequences of steps that are prescribed for the pharma manufacturing process. However, the disclosure is equally applicable to other areas, such as intrusion detection of a computer system or other processes.

More particularly, this disclosure relates to checking whether a technical process (e.g. manufacturing, chemical, server) complies with a set of rules. The rules may include thresholds on temperatures (e.g. 36.0<T<37.0) or other process parameters as well as sequences (e.g. granulation after milling). While the following disclosure provides a rigorous mathematical formulation, it is noted that the implication of following this formulation in practice is a significant decrease complexity which ultimately enables the compliance checking of complex process using existing hardware. In this sense, while this disclosure may be applicable to business processes, the real advantage and substance of this disclosure is towards the technical effect and contribution of reduced processing time and reduced amount of necessary computer memory.

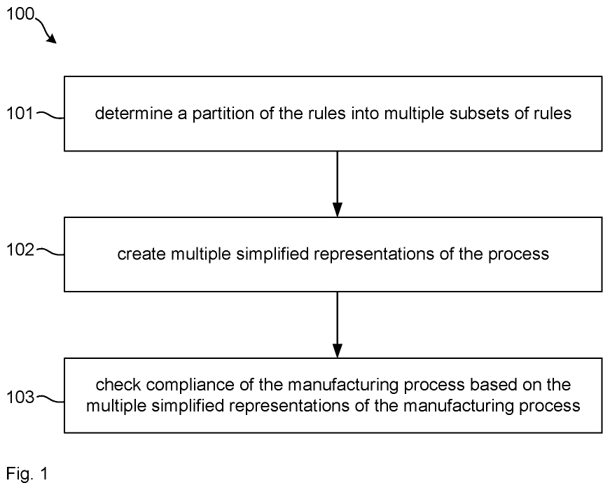

FIG. 1 illustrates a method 100 for monitoring a manufacturing process. The manufacturing process comprises multiple process parameters and multiple rules that use the multiple process parameters as literals. For example, a temperature may be a process parameter and it can be expressed as a Boolean literal by applying a threshold, so the literal T (for temperature) equals ‘1’ or TRUE if the temperature is within the required range and ‘0’ or FALSE if it is outside that range. The rule would then simply be T=1. However, there may also be a flow of coolant that needs to be turned off when the temperature is within the range leading to a rule T AND NOT C=1. As can be seen, there are already four different combinations for only two literals. This increases exponentially with the number of literals. Therefore, if the overall process has 20 parameters, there would be over 1 million combinations that could be combined.

In order to address this exponential grown, the method 100 comprises the step of determining 101 a partition of the rules into multiple subsets of rules. Each subset of rules is independent from the other subsets of rules in relation to the literals used in the respective rules. That is, each partition contains a subset of rules that have a (potentially transitive) dependency on each other. Rules in different partitions are independent from each other in the sense that they have disjoint sets of literals. Consider, for example, the following rules:
R₁: [symbol] ₁→ [symbol] ₂
R₂: [symbol] ₁→ [symbol] ₃
R₃: [symbol] ₄→ [symbol] ₅
R₄: [symbol] ₅→ [symbol] ₆, [symbol] ₇
R₅: [symbol] ₆→¬ [symbol] ₈
R₆: [symbol] ₉→¬ [symbol] ₁₀

From this set of rules, the following partitions can be obtained: {R₁, R₂}, {R₃, R₄, R₅} and {R₆}. It is noted that there may be exceptions for literals that are common to all rules, so there would be no partitioning possible without duplicating those literals into all of the partitions.

In one example, finding the partition comprises building a graph where each node represents a literal and an edge is created if the two connected literals are in the same rule. A clique finding algorithm, such as Bron and Kerbosch, can then be applied to the graph to find the cliques, which then form the partition (see: Coen Bron and Joep Kerbosch (1973): Algorithm 457: Finding All Cliques of an Undirected Graph. Communications of the ACM Vol. 16, Issue 9. ACM Press: New York, USA.)

After partitioning the rule set, the next step of method 100 is creating 102 multiple simplified representations of the process for each rule subset. Each of the multiple simplified representations comprises the one or more literals from a corresponding one of the multiple subsets of rules but the literals used in the other subsets are eliminated as described below. In one example, the simplified representations comprise Petri Nets, Prime Event Structures and Kripke structures.

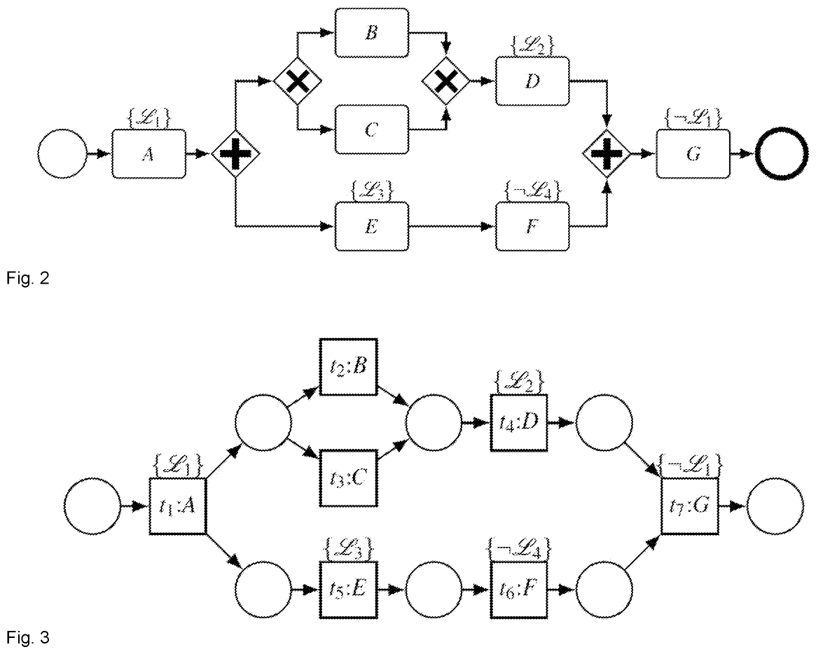

FIG. 2 illustrates an example for a process in the form of a Business Process Model and Notation (BPMN) annotated with literals that are used in compliance rules later on. BPMN is a graphical representation for specifying business processes in a business process model. More information about the BPMN specification can be found at http://www.bpmn.org/. While the BPMN in general is intended to provide businesses with the capability of understanding their internal business procedures in a graphical notation, it is used here as a precursor data structure to graph-based computer processes in order to achieve the desired outcome in a computationally efficient manner. However, other starting points can equally be chosen.

Technical processes can be modelled using many different notations. Often these notations require further formalisation before formal verification can be applied. BPMN, for example, is used to model technical processes. However, a BPMN model uses formalisation in order to allow for formal verification.

Petri nets (PN) are a modelling language used to formalise technical processes. Petri nets, or place/transition nets, are mathematical models for the description of distributed systems. Petri nets are directed bigraphs with nodes consisting of places and transitions. Transitions within Petri nets represent events while places represent conditions. Arcs form directed edges between place and transition pairs. Places may contain tokens. A distribution of tokens over places is called a marking. A transition is enabled and can “fire” when all its input places have at least one token. When a transition fires, one token is removed from each input place and one token is put into each output place.

The transformation from a BPMN process model to a corresponding Petri net uses a notion of unlabelled transitions (which are referred to as silent or r transitions) in order to realize the behaviour as defined by parallel gateways and exclusive branches. These unlabelled transitions will be eliminated during the construction of the event structure as discussed later.

FIG. 3 illustrates the result of the subsequent transformation from the BPMN model of FIG. 2 into a Petri net.

### Rule-Specific Petri Nets

In this example, only rule R₁: [symbol] ₁→ [symbol] ₂ (rule R₁) is considered for simplicity. When reducing for rule R₁, all transitions that do not involve [symbol] ₁ or [symbol] ₂ (i.e. literals of the other subsets) are made silent (i.e. eliminated) in the Petri net. In order to preserve stutter equivalence, activities that do not contain changes in any literal are included in the model, but treated differently when converting to the Kripke structure later on (as will be explained in detail below).

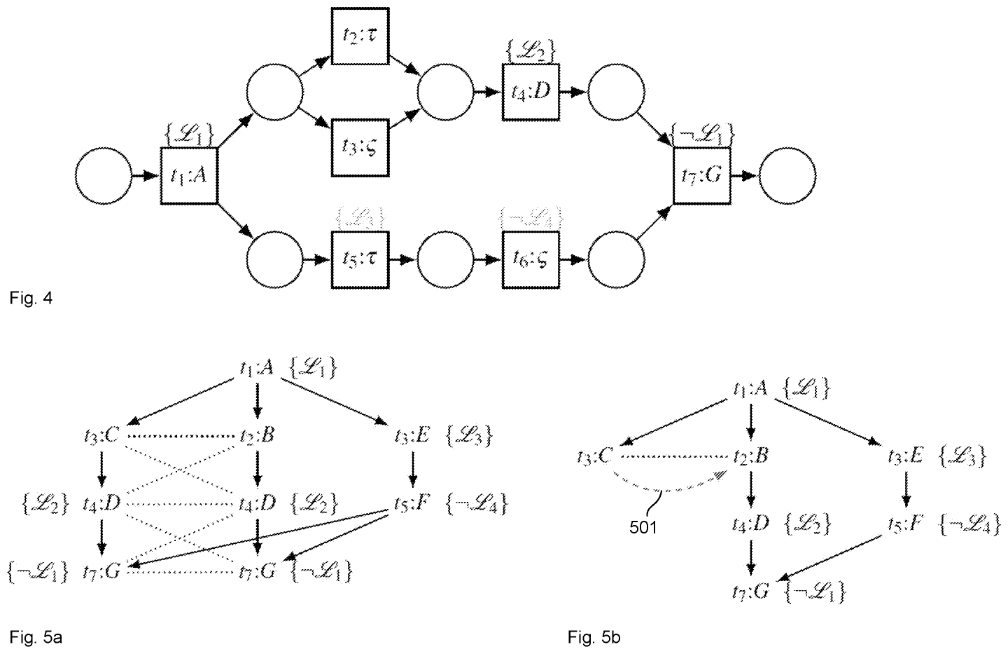

FIG. 4 shows a rule-specific Petri net as a result of applying R₁ to the Petri net in FIG. 3. Transitions labelled with τ are silent, while the transitions labelled with ζ are used to preserve stutter equivalence (and, hence, cannot be silent). For example, transition t₆ does not have relevant literals, as they are not part of the formula to be investigated (i.e. only literal of other subsets). However, t₆ cannot be invisible (due to stutter equivalence), but its literals are to be ignored in the Kripke, hence the label ζ. This ensures preservation of the behaviour of the process.

### Prime Event Structures and PES Prefix Unfoldings

A branching process is an alternative class of Petri nets that explicitly represents all partially-ordered runs of the original net in a single tree-like structure. A run of a net is a partially-ordered set of events that can occur in one execution of that net. A branching process comprises a set of behavioural relations between pairs of occurring events. The behavioural relations derived from the branching process generate a Prime Event Structure (PES). More information about PES is found in Glynn Winskel. An introduction to event structures. In: Proceeding Linear Time, Branching Time and Partial Order in Logics and Models for Concurrency, School/Workshop. Springer, 1989, which is included herein by reference. In particular, event structures are a model of computational processes. They represent a process as a set of event occurrences to express how events causally depend on others.

A PES is a graph of events, where each event e represents the occurrence of a task or activity in the business process. As such, multiple occurrences of the same activity are represented by different events. Events can have the following binary behaviour relations:

1. Causality (e<e′) indicates that event e is a prerequisite for e′;

2. Conflict (e #e′) implies that e and e′ cannot occur in the same run;

3. Concurrency (e∥e′) indicates that no order can be established between e and e′.

Transitions in the branching process correspond to events in the PES. Silent (or τ) events can be removed in a behaviour-preserving manner. This holds if every sink event in the event structure is a visible event. The branching process of a Petri net with loops is potentially infinite. For safe nets, however a prefix of a branching process fully encodes the behaviour of the original net. Such a prefix is referred to as the complete prefix unfolding of a net. To represent the behaviour specified by a BPMN process model, the method disclosed herein may use the PES derived from the complete prefix unfolding of the corresponding Petri net, which is referred to as the PES prefix unfolding of a model.

In a PES prefix unfolding, when 2 events share the same “future′” (like e.g. t₂: B and t₃: C), only one “future” is used to describe the behaviour of the process. As such, one event is called a cutoff event. The remaining events after the cutoff event can be removed from the PES and the cutoff event refers to its corresponding event. FIG. 5a shows an example of a PES while FIG. 5b shows a PES prefix unfolding. Causal relations are depicted as a solid arrow, whereas conflict relations are depicted as a dotted line. In this example, t₃: C is a cutoff event and t₂: B is a corresponding event. A cutoff and corresponding event are together referred to as a cc-pair, which is indicated with a dashed arrow 501. In other words, the unfolding of the full branching process/tree is stopped as soon as a familiar state is encountered and cutoffs and corresponding events are created to represent the “future” of the cutoff event without requiring duplicated subsequent events. This leads to a significant performance gain of this method as it reduces the complexity (number of nodes and edges) of the structures.

It can be seen that the computation of a PES prefix unfolding is the same as for a regular PES except that the method keeps track of cc-pairs (t₂: B and t₃: C), and does not abstract away a silent event when such event is either a cutoff or a corresponding event.

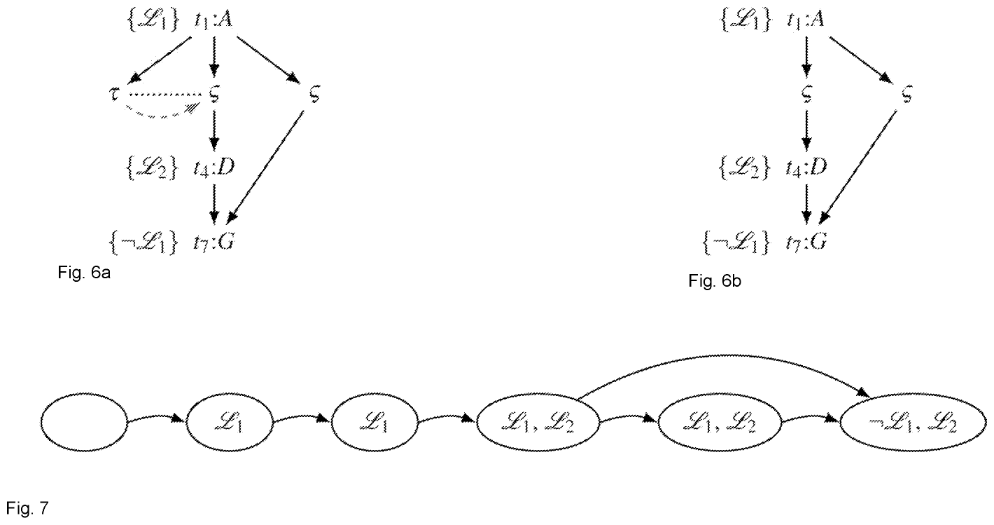

When generating a PES prefix unfolding for the Petri net in FIG. 4, τ transitions can be eliminated, unless they represent a cutoff or a corresponding event. FIG. 6a shows the direct prefix unfolding. However, the τ transition replacing t₃: C cannot be removed, as it is a cutoff event. Consequently, the PES prefix unfolding shows two silent events (τ and ζ) that are mutually exclusive but do not represent a literal. Therefore, they can be replaced by a single ζ event to retain stutter equivalence, as shown in FIG. 6b. Depending on the application and whether stutter equivalence is important, either of the representations in FIGS. 5b and 6b can be used as the simplified representations of the process created in step 102 of method 100. It is noted here that each of the multiple simplified representations in FIGS. 5b and 6b comprises the literals from their corresponding subset of rules. Therefore, there are multiple of those representations with one representation for each subset of rules.

### Transformation to Kripke Structures

The next step of method 100 in FIG. 1 is to check compliance 103 of the process based on the multiple simplified representations of the manufacturing process. In order to check the compliance of the process model in each state (i.e. there exists no state for which the process model is not compliant with the rules), the possible states of the model and the transitions between those states are captured in a model.

In general terms, the compliance check 103 may be based on a (labelled) transition system, with a transition relation defined as a subset of S×S, which may additionally be extended to include a set of atomic propositions and a labelling function for the states as well (L). In this approach, the binary relation obtained by abstracting away the action labels may be called a state graph.

More specifically, a Kripke structure may be used which also is a state-based labelled transition system that has a labelling function over its states and can be used as a system model for model checking. Let AP be a set of atomic propositions, i.e. Boolean expressions over variables, constants and predicate symbols. A Kripke structure may be defined over AP as a 4-tuple M=(S, I, R, L) consisting of
a finite set of states S.
a set of initial states I⊆S.
a transition relation R⊆S×S such that R is left-total, i.e., ∀s∈S∃s′∈S such that (s,s′)∈R.
a labelling (or interpretation) function L: S→2^{AP}.

Since R is left-total, it is always possible to construct an infinite path through the Kripke structure. A deadlock state can be modelled by a single outgoing edge back to itself. The labelling function L defines for each state s∈S the set L(s) of all atomic propositions that are valid in s.

A path of the structure M is a sequence of states ρ=s₁, s₂, s₃, . . . such that for each i>0, R(sᵢ, sᵢ₊₁) holds. The word on the path ρ is a sequence of sets of the atomic propositions w=L(s₁), L(s₂), L(s₃), . . . , which is an ω-word over alphabet 2^{AP}.

With this definition, a Kripke structure (say, having only one initial state i∈I) may be identified with a Moore machine with a singleton input alphabet, and with the output function being its labelling function.

The reduced PES prefix unfolding of FIG. 6b can be transformed into a Kripke structure. Every state in the Kripke structure represents a set of atomic propositions (AP). Each AP represents a literal of the transition that is enabled (i.e. can fire/execute) in that state. FIG. 7 shows the generated Kripke from the reduced PES prefix unfolding of FIG. 6b.

### Linearisation of Independent Concurrent Branches

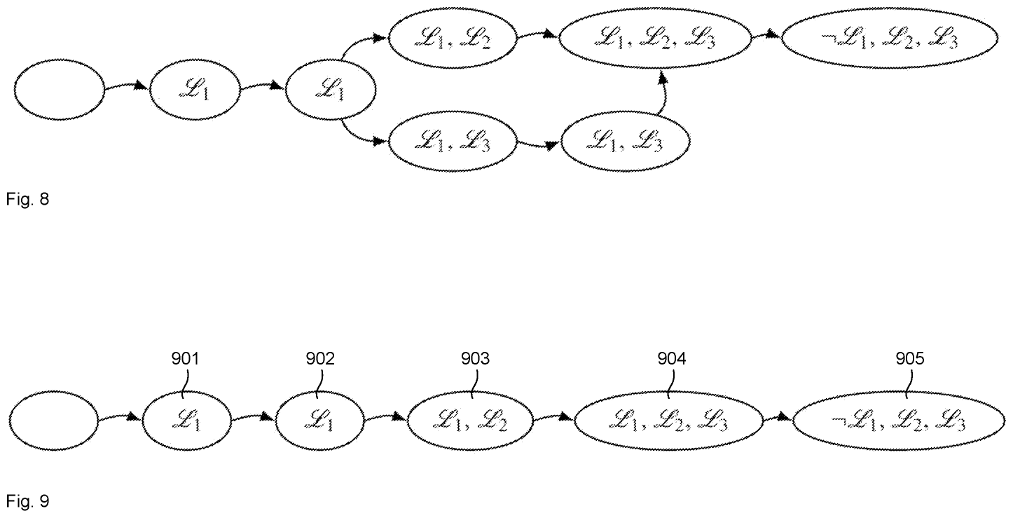

Consider the Petri net as shown in FIG. 3. If there are two rules R₁: [symbol] ₁→ [symbol] ₂ and R₂: [symbol] ₁→ [symbol] ₃, both concurrent branches are required in the reduced model, but the branches have no dependencies to each other. The resulting Kripke structure based on R₁ and R₂ using the presented method is shown graphically in FIG. 8.

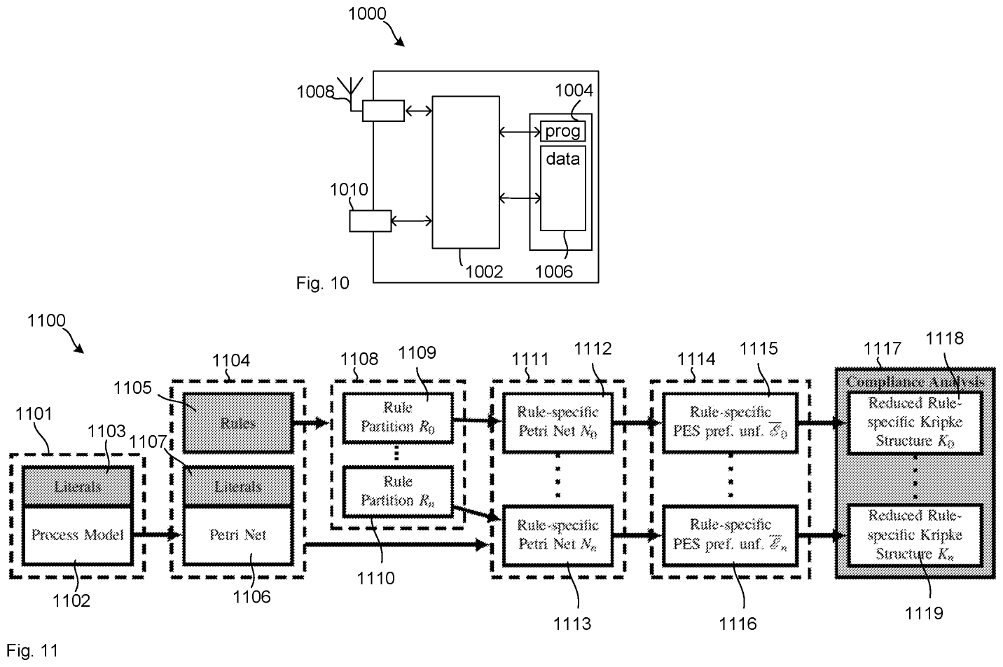

As such, computing the interleavings during the compliance analysis is unnecessary as each interleaving would render the same result. Therefore, there is proposed an additional reduction step, where independent concurrent branches may be linearized. Consequently, only one interleaving is created and used to evaluate the compliance to the rules. The resulting linearized Kripke structure is shown in FIG. 9.

As a result, the manufacturing process can be checked against the rules by checking compliance 103 of the manufacturing process based on the multiple simplified representations of the manufacturing process. This is performed by comparing values of the literals of a current process execution (e.g. current temperature) against literals in the multiple simplified representations (i.e. Kripke structures, other state model or state graph). In this way, the literals of the process are checked to ensure that they represent a valid transition in the Kripke structure. This can be performed in parallel for all subsets of rules.

For example, in the simplified representation shown in FIG. 9, at the beginning of the process, the first node 901 is labelled [symbol] ₁, which means that the process is compliant if the first literal is TRUE (such as the temperature is within the nominal range). The remaining literals are irrelevant at this stage and the same applies to the second state 902. In the third state 903, however, both literals [symbol] ₁ and [symbol] ₂ must be TRUE, while in the fourth state 904 all four literals [symbol] ₁, [symbol] ₂ and [symbol] ₃ must be TRUE or otherwise the process is not compliant. During the transition to the fifth state 905, the first literal [symbol] ₁ has to switch to FALSE while the remaining two literals [symbol] ₂ and [symbol] ₃ must remain TRUE.

This shows how the process can be checked while, at the same time operating on a model with a small number of nodes despite the total number of possible combinations without per-rule simplification being prohibitive.

If there is a difference between the literal values in the Kripke structure and the process parameter values, the manufacturing process can be adjusted. This may comprise controlling actuators, such as valves, heaters or coolers to directly control the process parameters or adjust the amount of material that enters the process. The compliance check in step 103 and the adjustment can then be repeated until no differences are identified, that is, the process is compliant. Step 103 may be repeated without adjustment throughout the entire operation of the process to ensure that deviations or non-compliance is detected early to provide timely intervention.

In summary, a process that is represented by a process model, such as BPMN or Petri Net. These models are typically not state-based as they represent parallel execution efficiently, for example. The process model is replicated for each independent subset of rules and each replica is simplified based on which literals are in that corresponding rule and when appropriate PES prefix unfoldings. The simplified representation may be in the form of a prime event structure, which is now a state-based representation. Finally, the resulting representation is converted to a Kripke structure which allows efficient checking of literals in each state. In this context, it is noted that the simplified representation is not converted back to the original format of the process model representation, such as BPMN. Nevertheless, the simplified Kripke structure is referred to as a simplified representation of the manufacturing process because it represents the manufacturing process in light of the rule set that was used to simplify this copy of the process.

FIG. 10 illustrates a computer system 1000 for monitoring a process. The computer system 1000 comprises a processor 1002 connected to a program memory 1004, a data memory 1006, a communication port 1008 and a user port 1010. The program memory 1004 is a non-transitory computer readable medium, such as a hard drive, a solid state disk or CD-ROM. Software, that is, an executable program stored on program memory 1004 causes the processor 1002 to perform the method in FIG. 1, that is, processor 1002 determines a partition into subsets of rules, creates a simplified representation of the process for each subset and checks compliance based on the literals in that subset. The term “determining a partition” or “creating a representation” refers to calculating parameter values that are indicative of the partition or representation. This also applies to related terms. The representations and/or partitions may be stored as text files, relational databases or preferably in graph-based databases for more efficient operations.

The processor 1002 may then store the representations on data store 1006, such as on RAM or a processor register. The processor 1002 may receive data, such as current process parameters (i.e. literal values), from data memory 1006 as well as from the communications port 1008 and the user port 1010, which is connected to a display that shows a visual representation of the current operation of the process to a user.

In one example, the user port 1010 may act as an output port that provides an indication of the check of compliance to a user in the form of a text message, website (writing web-accessible HTML) or on a computer display. User port 1010 may also be connected to an alarm mechanism, such as a buzzer or alarm light to indicate out of compliance of time/safety-critical processes. Each of the partitions of the rules may also be provided with a label that represents the high-level functionality of that partition. This way, the indication to the user can include the high-level label instead of a potentially long list of literals that have caused non-compliance.

In one example, the processor 1002 receives current process parameters from sensors via communications port 1008, such as by using a Wi-Fi network according to IEEE 802.11. The Wi-Fi network may be a decentralised ad-hoc network, such that no dedicated management infrastructure, such as a router, is required or a centralised network with a router or access point managing the network. The sensors may be remote sensors connected via satellite communications and independent power supply.

In one example, the processor 1002 receives and processes the current process parameters in real time. This means that the processor 1002 checks compliance of the process every time current process data is received from the sensors and completes this calculation before the sensors send the next sensor data update.

Although communications port 1008 and user port 1010 are shown as distinct entities, it is to be understood that any kind of data port may be used to receive data, such as a network connection, a memory interface, a pin of the chip package of processor 1002, or logical ports, such as IP sockets or parameters of functions stored on program memory 1004 and executed by processor 1002. These parameters may be stored on data memory 1006 and may be handled by-value or by-reference, that is, as a pointer, in the source code.

The processor 1002 may receive data through all these interfaces, which includes memory access of volatile memory, such as cache or RAM, or non-volatile memory, such as an optical disk drive, hard disk drive, storage server or cloud storage. The computer system 1000 may further be implemented within a cloud computing environment, such as a managed group of interconnected servers hosting a dynamic number of virtual machines.

It is to be understood that any receiving step may be preceded by the processor 1002 determining or computing the data that is later received. For example, the processor 1002 determines a current process parameter and stores it in data memory 1006, such as RAM or a processor register. The processor 1002 then requests the data from the data memory 1006, such as by providing a read signal together with a memory address. The data memory 1006 provides the data as a voltage signal on a physical bit line and the processor 1002 receives the parameter value via a memory interface.

It is to be understood that throughout this disclosure unless stated otherwise, nodes, edges, graphs, solutions, variables, models and the like refer to data structures, which are physically stored on data memory 1006 or processed by processor 1002. Further, for the sake of brevity when reference is made to particular variable names, such as “period of time” or “compliance” this is to be understood to refer to values of variables stored as physical data in computer system 1000.

Further, FIG. 1 is to be understood as a blueprint for the software program and may be implemented step-by-step, such that each step in FIG. 1 is represented by a function in a programming language, such as C++ or Java. The resulting source code is then compiled and stored as computer executable instructions on program memory 1004.

In further examples, processor 1002 may generate a visual representation of the process model, such as a visual representation of the Petri nets or BPMNs described herein. Further, processor 1002 may generate a graphical user interface showing that the process is currently compliant. Upon determining that the process is not compliant (i.e. the literals in the simplified representations do not match to the current process parameters), processor 1002 changes the graphical user interface to indicate non-compliance.

For example, processor 1002 may generate a visual representation of the simplified representation of the process where non-compliance occurred. For the user, this narrows the set of rules significantly and allows quick intervention by the user. This is particularly advantageous in user interfaces to control a technically complex system. For example, a pilot of a modern aircraft needs to constantly monitor a large number of different parameters. If non-compliance occurs, this may lead to a large number of error messages due to interrelated technical systems. This may quickly exceed the cognitive capability the pilot. With the proposed system, however, the independent rule-sets are isolated, which means that in many cases, only one of those sets may be affected. As a result, instead of showing hundreds of error messages, the in-flight system may show only the descriptor of the independent rule set where non-compliance occurred to indicate to the pilot the general area of non-compliance, such as the left engine, for example.

FIG. 11 illustrates method 100 from FIG. 1 in a data flow representation 1100. In this sense, FIG. 11 can be implemented in an object orientated manner where each of the dashed boxes in FIG. 11 illustrate the data objects and the method steps in FIG. 1 represent the arrows that create the next data object (from left to right). The data objects may also be described as modules or separate computer instances, such as virtual machines on a cloud computing platform. An input data object 1101 comprises a process model 1102, such as a model in BPMN notation. Processor 1102 may automatically extract multiple literals 1103 or the literals may be provided together with the process model. The process model may be provided as a data file or entered by the user.

Processor 1002 then creates global rules data object 1104 holding a set of rules 1105. Global in this sense means the rules are applicable or have scope across the entire process. Processor 1002 also converts the process model 1102 into a Petri net 1106 while maintaining the set of literals 1107. Based on the rules 1105, which are global at this stage, processor 1002 creates a partition data object 1108 holding multiple partitions 1109, 1110 represented by subsets of the rules which implies a subset of literals. While the two example partitions 1109, 1110 are shown in FIG. 11, it is noted that in practice the number of partitions would be greater than two as indicated by the dots and the index n.

In a Petri Net collection data object 1111, there are rule-specific Petri Nets 1112, 1113 that processor 1002 creates for each rule partition by simplifying Petri Net 1106 from the global rules data object 1105 for that particular rule. This is achieved as described above by making nodes silent where the literal of that node is included in the other rules but not the current rule for that rule-specific Petri net.

Once the Petri nets in the Petri net collection data object 1111 are simplified, processor 1002 generates an event structure collection data object 1114 including for each rule-specific Petri net a prime event structure 1115, 1116 for that rule 1109, 1110, respectively. The prime event structures and/or the prefix unfoldings of event structures in collection 1115 are further simplified as shown above. Finally, processor 1002 creates a compliance collection data object 1117 by creating for each rule-specific prime event structure 1115, 1116 a state-based representation 1118, 1119, respectively, such as a Kripke Structure. Processor 1002 can now step through each Kripke Structure in 1118 and determine whether the conditions in each state of the Kripke structure are the same as the current process parameters (such as from sensors in the manufacturing process).

It is noted that in FIG. 11, starting from the partition data object 1108, the processing of each rule partition occurs in parallel. This means, FIG. 11 can be divided at this stage into multiple horizontal rows, where each row can be processed in parallel. This lends itself to implementation in a cloud computing environment where a separate processing instance can be created for each rule partition in order to accelerate the compliance checking. These processing instances may be synchronised in the sense that they wait for the other instances to finish before they perform the next check. In other examples, each processing instance is asynchronous as non-compliance is detected if one of the instances flags non-compliance. Therefore, it is insignificant if each instance/partition is performed on a set of process parameters that have been sampled at different times. The output of non-compliance of one of those partitions would still be accurate for compliance checking. At the same time, the parallel processing provides a significant further technical advantage of reduced overall processing time. Since the sets of literals are independent of each other, the parallelisation is simplified as the individual parallel branches do not need to be synchronised, which results in a further speed-up.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A method for manufacturing a pharmaceutical compound according to a manufacturing process, the manufacturing process comprising multiple process parameters and multiple rules that use the multiple process parameters as literals, the method comprising:
determining a partition of the rules into multiple subsets of rules, each subset of rules being independent from the other subsets of rules in relation to the literals used in the respective rules;
creating multiple simplified representations of the manufacturing process, wherein each of the multiple simplified representations comprises the one or more literals from a corresponding one of the multiple subsets of rules and is created by eliminating literals used by other subsets of rules;
checking compliance of the manufacturing process based on the multiple simplified representations of the manufacturing process by comparing values of the literals of a current process execution against literals in the multiple simplified representations;
adjusting the manufacturing process where the comparing identifies a difference; and
repeating the steps of checking and adjusting until no differences are identified.

2. A method for monitoring a process, the process comprising multiple process parameters and multiple rules that use the multiple process parameters as literals, the method comprising:
determining a partition of the rules into multiple subsets of rules, each subset of rules being independent from the other subsets of rules in relation to the literals used in the respective rules;
creating multiple simplified representations of the process, wherein each of the multiple simplified representations comprises the one or more literals from a corresponding one of the multiple subsets of rules and is created by eliminating literals used by other subsets of rules;
checking compliance of the manufacturing process based on the multiple simplified representations of the manufacturing process by comparing values of the literals of a current process execution against literals in the multiple simplified representations.

3. The method of claim 2, wherein creating each of the multiple simplified representations comprise creating a directed graph with nodes consisting of places and transitions.

4. The method of claim 3, wherein the directed graph is a petri net.

5. The method claim 3, wherein creating the multiple simplified representations comprises labelling nodes in the graph as silent where the literal corresponding to that node is not included in the corresponding one of the multiple subsets of rules.

6. The method of claim 5 wherein creating the multiple simplified representations comprises simplifying the graph by removing silent nodes.

7. The method of claim 6, wherein creating the multiple simplified representations comprises creating a graph including states such that the process is in one of the states of the representation.

8. The method of claim 7, wherein the graph is a prime event structure and the method comprises simplifying the prime event structure by removing silent nodes associated with the literals from the other subset of rules.

9. The method of claim 8, wherein removing the silent nodes is performed in a behaviour-preserving manner.

10. The method of claim 2, further comprising converting the simplified representation of the manufacturing process to a Kripke structure and checking compliance based on the Kripke structure.

11. The method of claim 10, further comprising linearising independent concurrent branches of the Kripke structure.

12. The method of claim 2, wherein the multiple simplified representations comprise states associated with values for literals and checking each of the multiple simplified representations comprises traversing the states according to the current process execution and at each state comparing values of the literals of the current process execution against the literals of the current state in the simplified representation.

13. The method of claim 2, further comprising, upon determining non-compliance by detecting a difference between the values of the literals of the current process execution and the literals of one of the multiple simplified structures, generating a graphical user interface indicative of the one of the multiple simplified structures for which the difference was detected.

14. The method of claim 13, wherein the graphical user interface is indicative of the subset of rules that is associated with the one of the multiple simplified structures for which the difference was detected.

15. The method of claim 14, wherein the user interface is indicative of the one or more literals from that subset of rules.

16. Computer software that, when executed by a computer system, causes the computer system to perform the method of claim 2.

17. A computer system for monitoring a process, the computer system comprising:
a computer memory to store multiple process parameters and multiple rules that use the multiple process parameters as literals;
a processor configured to:
determine a partition of the rules into multiple subsets of rules, each subset of rules being independent from the other subsets of rules in relation to the literals used in the respective rules;
create multiple simplified representations of the process, wherein each of the multiple simplified representations comprises the one or more literals from a corresponding one of the multiple subsets of rules and is created by eliminating literals used by other subsets of rules;
check compliance of the manufacturing process based on the multiple simplified representations of the manufacturing process by comparing values of the literals of a current process execution against literals in the multiple simplified representations; and
an output port to provide an indication of the check of compliance to a user.
